(19) United States
(12) Patent Application Publication
(10) Pub. No.: US 2026/0020266 A1
(43) Pub. Date: Jan. 15, 2026

(54) Semiconductor capacitor structure

(71) Applicant: REALTEK SEMICONDUCTOR CORPORATION, Hsinchu (TW)

(72) Inventor: SHIH-HSIUNG HUANG, Hsinchu (TW)

(21) Appl. No.: 19/189,987

(22) Filed: Apr. 25, 2025

(30) Foreign Application Priority Data
Jul. 10, 2024 (TW) 113125913

(51) Int. Cl. H10D 1/68

(52) U.S. Cl. CPC H10D 1/714

(57) ABSTRACT

A semiconductor capacitor structure includes a part on a routing-direction-non-turnable metal layer and a part on a routing-direction-turnable metal layer. The semiconductor capacitor structure includes: a first electrode unit layout located on the routing-direction-non-turnable metal layer, wherein all metal traces of the first electrode unit layout are parallel to a first direction; a second electrode unit layout located on the routing-direction-turnable metal layer, wherein each of a first potential part and a second potential part of the second electrode unit layout includes metal lines parallel to the first direction and metal lines parallel to a second direction; and a dielectric located between the first and the second potential parts of the second electrode unit layout, wherein at least a part of the metal traces of the first electrode unit layout is coupled to the first potential part of the second electrode unit layout through at least one via.

### BACKGROUND OF THE INVENTION

### 1. Field of the Invention

The present disclosure relates to a capacitor structure, especially to a semiconductor capacitor structure of an integrated circuit.

### 2. Description of Related Art

FIG. 1 shows a conventional semiconductor capacitor array 100 of an integrated circuit (IC). This capacitor array 100 can be applied to a successive-approximation register analog-to-digital converter (SAR ADC). As shown in FIG. 1, one end of each capacitor of the conventional semiconductor capacitor array 100 is coupled to a lower electrode plate 102 while the other end is coupled to an electrode plate of a reference voltage VR or an electrode plate of a ground voltage GND through a switch 104. The conventional semiconductor capacitor array 100 includes a plurality of capacitors 1C, 1C, 2C, 4C, 8C, 16C, 32C, 64C, 128C, etc., where 1C represents one unit capacitor, 2C represents two unit capacitors, and so on. The unit capacitor is, for example, a metal-oxide-metal (MOM) unit capacitor, and its structure can be determined according to the manufacturing process or the designer's preference.

Referring to FIG. 1, each MOM unit capacitor of the conventional semiconductor capacitor array 100 is formed on a metal layer of the IC. When the conventional semiconductor capacitor array 100 is manufactured with an advanced process (e.g., 16 nanometer (nm) process, 7 nm process, 5 nm process, or 3 nm process), the metal traces of the conventional semiconductor capacitor array 100 must comply with the design limitations of the advanced process on the routing direction of the metal traces. For example, in order from the substrate of the IC upward: the routing direction of the metal traces located on a first metal layer (hereinafter referred to as metal layer 1) of the IC can only be the lateral direction (hereinafter referred to as X direction) on a plane; the routing direction of the metal traces located on the next metal layer (hereinafter referred to as metal layer 2) of the IC can only be the longitudinal direction (hereinafter referred to as Y direction) on the plane; the routing direction of the metal traces located on the next metal layer (hereinafter referred to as metal layer 3) of the IC can be the X direction or the Y direction, and choosing the X direction is advantageous to reduce the spacing between metal traces; and the routing direction of the metal traces located on the next one or two metal layer(s) (hereinafter referred to as metal layer 4, or metal layers 4 and 5) of the IC can be the X direction or the Y direction, and choosing either direction does not affect the spacing between metal traces. The metal layers 1 and 2 are called routing-direction-non-turnable metal layers, and the above-mentioned metal layers 3, 4 and 5 are called routing-direction-turnable metal layers. The above-mentioned design limitations restrict the design of the MOM capacitor architecture, making it difficult to further increase the capacitance of the conventional semiconductor capacitor array 100. It is noted that the X and Y directions can be redefined as the longitudinal and lateral directions on a plane respectively, but this does not affect their actual meaning.

In consideration of the design limitations of the advanced process on the routing direction of the metal traces, the conventional semiconductor capacitor array 100 is formed on a routing-direction-turnable metal layer or a routing-direction-non-turnable metal layer. More specifically, each MOM unit capacitor of the conventional semiconductor capacitor array 100 is not formed on both the routing-direction-turnable metal layer and the routing-direction-non-turnable metal layer.

### SUMMARY OF THE INVENTION

One objective of the present disclosure is to propose a semiconductor capacitor structure of an integrated circuit (IC). The semiconductor capacitor structure includes a part formed on a routing-direction-turnable metal layer of the IC and a part formed on a routing-direction-non-turnable metal layer of the IC.

According to an embodiment of the semiconductor capacitor structure of the IC of the present disclosure, the IC includes a routing-direction-non-turnable metal layer and a routing-direction-turnable metal layer, and the semiconductor capacitor structure includes a first electrode unit layout, a second electrode unit layout, and a dielectric. The first electrode unit layout is located on the routing-direction-non-turnable metal layer, wherein all metal traces located on the routing-direction-non-turnable metal layer including metal traces of the first electrode unit layout are parallel to a first direction (e.g., the aforementioned Y direction). The second electrode unit layout is located on the routing-direction-turnable metal layer and includes a first potential part and a second potential part, wherein each of the first potential part and the second potential part includes metal traces parallel to the first direction and metal traces parallel to a second direction (e.g., the aforementioned X direction), the first potential part is coupled to a first voltage terminal used to provide a first voltage, and the second potential part is coupled to a second voltage terminal used to provide a second voltage different from the first voltage. The dielectric is located between the first potential part and the second potential part. It is noted that at least a part of the metal traces of the first electrode unit layout is electrically connected to the first potential part of the second electrode unit layout through at least one via.

According to another embodiment of the semiconductor capacitor structure of the IC of the present disclosure, the IC includes a routing-direction-non-turnable metal layer and a routing-direction-turnable metal layer, and the semiconductor capacitor structure includes a first electrode unit layout, a dielectric, and a second electrode unit layout. The first electrode unit layout is located on the routing-direction-non-turnable metal layer, wherein all metal traces located on the routing-direction-non-turnable metal layer including metal traces of the first electrode unit layout are parallel to a first direction (e.g., the aforementioned Y direction), the metal traces of the first electrode unit layout include a first potential part and a second potential part, the first potential part is coupled to a first voltage terminal used to provide a first voltage, and the second potential part is coupled to a second voltage terminal used to provide a second voltage different from the first voltage. The dielectric is located between the first potential part and the second potential part. The second electrode unit layout is located on the routing-direction-turnable metal layer, wherein metal traces of the second electrode unit layout include a part parallel to the first direction and another part parallel to a second direction (e.g., the aforementioned X direction). It is noted that the first potential part of the metal traces of the first electrode unit layout is electrically connected to at least a part of the metal traces of the second electrode unit layout through at least one via.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows a conventional semiconductor capacitor array of an integrated circuit (IC).

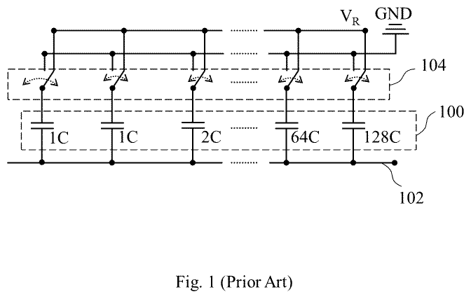

FIG. 2 shows an embodiment of the semiconductor capacitor structure of an IC of the present disclosure.

FIG. 3 shows an embodiment of the first electrode unit layout of FIG. 1.

FIG. 4 shows an embodiment of the second electrode unit layout of FIG. 1.

FIG. 5 shows another embodiment of the semiconductor capacitor structure of an IC of the present disclosure.

FIG. 6 shows an embodiment of the third electrode unit layout of FIG. 5.

FIG. 7 shows yet another embodiment of the semiconductor capacitor structure of an IC of the present disclosure.

FIG. 8 shows an embodiment of the fourth electrode unit layout of FIG. 7.

### DETAILED DESCRIPTION OF THE PREFERRED EMBODIMENTS

There are currently a variety of known semiconductor capacitor structures of integrated circuits, such as the metal-oxide-metal (MOM) unit capacitor structures disclosed in the applicant's US patents U.S. Pat. No. 10,374,625B2, U.S. Pat. No. 11,810,916B2, and U.S. Pat. No. 11,837,597B2 and the applicant's US patent application Publication US2022/0367447A1. The structure of each MOM unit capacitor structure mentioned above is formed on a routing-direction-turnable metal layer or a routing-direction-non-turnable metal layer, rather than on both a routing-direction-turnable metal layer and a routing-direction-non-turnable metal layer. In order to further increase the capacitance of a semiconductor capacitor structure under the design limitations of an advanced process on the routing direction of metal traces, this specification discloses a semiconductor capacitor structure including a part formed on a routing-direction-turnable metal layer and a part formed on a routing-direction-non-turnable metal layer. It is noted that any metal trace located on the routing-direction-turnable metal layer can optionally be parallel to a first direction (e.g., the aforementioned X direction) or a second direction (e.g., the aforementioned Y direction), while all metal traces located on the routing-direction-non-turnable metal layer are parallel to the same direction (e.g., one of the X direction and the Y direction).

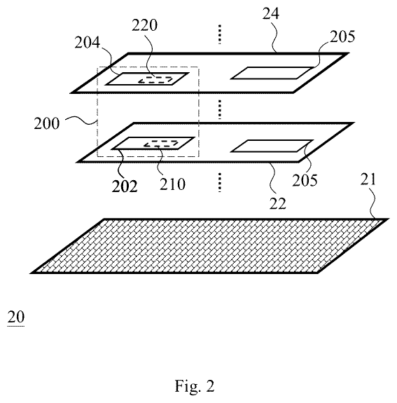

FIG. 2 shows an embodiment of the semiconductor capacitor structure of an IC of the present disclosure. The IC 20 of FIG. 2 includes a substrate 21, a first routing-direction-non-turnable metal layer 22 (e.g., the first or second metal layer of a general IC), and a first routing-direction-turnable metal layer 24 (e.g., the third, fourth, or fifth metal layer of a general IC). There may be other structures (e.g., other integrated circuit layers, as illustrated with the dotted lines in FIG. 2) between the first routing-direction-non-turnable metal layer 22 and the first routing-direction-turnable metal layer 24, or under the first routing-direction-non-turnable metal layer 22, or above the first routing-direction-turnable metal layer 24, but the implementation of the present invention is not limited thereto. It is noted that the first routing-direction-non-turnable metal layer 22 is relatively close to the substrate 21 and the first routing-direction-turnable metal layer 24 is relatively far away from the substrate 21. The above relationship can be directly learned from the figures. It is also noted that an IC composed of multiple layers are known in the art.

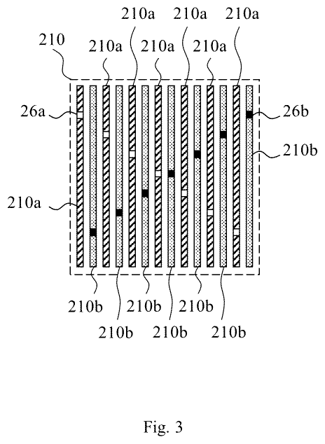

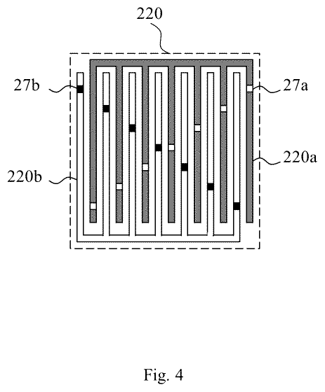

Referring to FIG. 2, in the IC 20, the analog circuit layout area and the digital circuit layout area are two different layout areas. Analog circuit components are formed in the analog circuit layout area while a power mesh in this area is usually sparse and irregular. On the contrary, digital circuit components are formed in a certain area of the substrate 21 pertaining to the digital circuit layout area while a dense and regular power mesh is formed on the area of each metal layer above the certain area of the substrate 21 to supply power to the underlying digital circuit components. Different circuit layout areas are preferred because digital circuit components and analog circuit components have distinct characteristics and need to be separated during operation to avoid negative effects. Generally, capacitors are formed in the analog circuit layout area, and sometimes they are formed in the digital circuit layout area due to design requirements. In this embodiment, at least one of the first routing-direction-non-turnable metal layer 22 and the first routing-direction-turnable metal layer 24 includes an analog circuit layout area and a digital circuit layout area 205, and a semiconductor capacitor structure 200 is formed in the analog circuit layout area. As shown in FIG. 2, the semiconductor capacitor structure 200 is formed on both the first routing-direction-non-turnable metal layer 22 and the first routing-direction-turnable metal layer 24. The semiconductor capacitor structure 200 includes a capacitor structure 202 (including an electrode of the semiconductor capacitor structure 200) located in the analog circuit layout area of the first routing-direction-non-turnable metal layer 22 and a capacitor structure 204 (including an electrode of the semiconductor capacitor structure 200) located in the analog circuit layout area of the first routing-direction-turnable metal layer 24. In an implementation example, the capacitor structure 204 alone acts as a capacitor while the capacitor structure 202 alone does not act as a capacitor but it is electrically connected to the capacitor structure 204 through at least one via (e.g., vias 26a and 26b in FIG. 3 that are represented by white and black squares respectively) to increase the capacitance of the semiconductor capacitor structure 200. In an implementation example, the capacitor structure 202 alone acts a capacitor while the capacitor structure 204 alone does not act as a capacitor but it is electrically connected to the capacitor structure 202 through at least one via (e.g., vias 27a and 27b in FIG. 4 that are represented by white and black squares respectively) to increase the capacitance of the semiconductor capacitor structure 200. In an implementation example, the capacitor structure 204 alone acts as a capacitor while the capacitor structure 202 alone also acts as a capacitor and is electrically connected to the capacitor structure 204 through at least one via to increase the capacitance of the semiconductor capacitor structure 200. It is noted that the at least one via in each of the above-mentioned implementation examples is not necessarily included in the semiconductor capacitor structure 200; in other words, the at least one via may be set outside the semiconductor capacitor structure 200 and the capacitor structures 202 and 204 can be coupled to the at least one via through metal traces and thereby be electrically connected together.

Referring to FIG. 2, the capacitor structure 202 includes a plurality of identical/similar unit layouts including a first electrode unit layout 210. Similarly, the capacitor structure 204 includes a plurality of identical/similar unit layouts including a second electrode unit layout 220. FIG. 3 shows an embodiment of the first electrode unit layout 210 of FIG. 2, and FIG. 4 shows an embodiment of the second electrode unit layout 220 of FIG. 2.

Referring to FIG. 3, all metal traces of the first electrode unit layout 210 (i.e., the metal traces 210a of the oblique pattern and the metal traces 210b of the dot pattern in FIG. 3) are parallel to a first direction (e.g., the Y direction). Referring to FIG. 4, the second electrode unit layout 220 includes a first part and a second part, wherein the metal traces of the first part (i.e., the gray metal traces 220a in FIG. 4) include metal traces parallel to the first direction (e.g., the Y direction) and metal traces parallel to a second direction (e.g., the X direction) and the metal traces of the second part (i.e., the white metal traces 220b in FIG. 4) also include metal traces parallel to the first direction and metal traces parallel to the second direction.

In an implementation example, the metal traces 220a of the first part of the second electrode unit layout 220 and the metal traces 220b of the second part of the second electrode unit layout 220 are respectively coupled to a first voltage terminal (not shown in the figures) and a second voltage terminal (not shown in the figure). The first voltage terminal and the second voltage terminal are respectively used to provide a first voltage (e.g., the operating voltage VDD of the IC 20) and a second voltage (e.g., the ground voltage GND of the IC 20). Based on the above, there is a dielectric (e.g., oxide) (not shown in the figures) between the metal traces 220a and the metal traces 220b so that the second electrode unit layout 220 itself acts as an MOM capacitor. In an implementation example, the metal traces 220a of the first part of the second electrode unit layout 220 and the metal traces 220b of the second part of the second electrode unit layout 220 are coupled to the same voltage terminal (i.e., one of the first voltage terminal and the second voltage terminal) so that the second electrode unit layout 220 alone does not contribute capacitance; in this case, the metal traces of a first part of the first electrode unit layout 210 (i.e., the metal traces 210a of the oblique pattern in FIG. 3) are electrically connected to the first voltage terminal, the metal traces of a second part of the first electrode unit layout 210 (i.e., the metal traces 210b of the dot pattern in FIG. 3) are electrically connected to the second voltage terminal, and there is a dielectric between the metal traces 210a and the metal traces 210b so that the first electrode unit layout 210 itself acts as an MOM capacitor. To sum up, one or each of the first electrode unit layout 210 and the second electrode unit layout 220 alone acts as an MOM capacitor.

Referring to FIGS. 2 to 4, depending on implementation requirements, the via 26a (i.e., any white square on the metal traces 210a of the oblique pattern in FIG. 3) can be used to electrically connect the metal traces 210a of the first part of the first electrode unit layout 210 to the metal traces 220a of the first part of the second electrode unit layout 220 or to the metal traces 220b of the second part of the second electrode unit layout 220; furthermore, the via 26b (i.e., any black square on the metal traces 210b of the dot pattern in FIG. 3) can be used to electrically connect the metal traces 210b of the second part of the first electrode unit layout 210 to the metal traces 220b of the second part of the second electrode unit layout 220 or to the metal traces 220a of the first part of the second electrode unit layout 220.

Referring to FIGS. 2 to 4, in order to further increase the capacitance of the semiconductor capacitor structure 200, when the metal traces 210a and the metal traces 220b are electrically connected to different voltage terminals, the position of the metal traces 210a is aligned with to the position of the longitudinal part (i.e., the part of the routing direction the same as that of the metal traces 210a) of the metal traces 220b to efficiently contribute capacitance. Similarly, when the metal traces 210b and the metal traces 220a are electrically connected to different voltage terminals, the position of the metal traces 210b is aligned with the position of the longitudinal part (i.e., the part of the routing direction the same as that of the metal traces 210b) of the metal traces 220a to efficiently contribute capacitance. It is noted that the implementation of the present invention is not limited to the above-mentioned alignment features.

Referring to FIGS. 2 to 4, the size and position of the first electrode unit layout 210 correspond to the size and position of the second electrode unit layout 220 to improve the compactness of the semiconductor capacitor structure 200; in addition, there is a dielectric between at least a part of the metal traces of the first electrode unit layout 210 and at least a part of the metal traces of the second electrode unit layout 220 to increase the overall capacitance of the semiconductor capacitor structure 200. In an implementation example, the area of the first electrode unit layout 210 is no greater than the area of the second electrode unit layout 220, and the first electrode unit layout 210 is located directly below the second electrode unit layout 220; in other words, the range of the first electrode unit layout 210 is completely included in the range of the downward vertical projection of the second electrode unit layout 220. In an implementation example, the area of the second electrode unit layout 220 is no greater than the area of the first electrode unit layout 210, and the second electrode unit layout 220 is located directly above the first electrode unit layout 210; in other words, the range of the second electrode unit layout 220 is completely included in the range of the upward vertical projection of the first electrode unit layout 210.

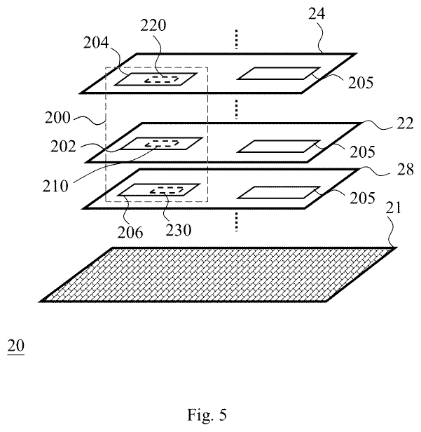

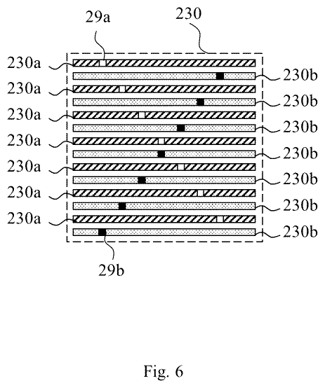

FIG. 5 shows another embodiment of the semiconductor capacitor structure of an IC of the present disclosure. Compared with FIG. 2, the IC 20 of FIG. 5 further includes a second routing-direction-non-turnable metal layer 28, and the semiconductor capacitor structure 200 includes a part formed on the first routing-direction-non-turnable metal layer 22, a part formed on the second routing-direction-non-turnable metal layer 28, and a part formed on the first routing-direction-turnable metal layer 24. In addition to the aforementioned capacitor structures 202 and 204, the semiconductor capacitor structure 200 further includes: a capacitor structure 206 located on the second routing-direction-non-turnable metal layer 28, wherein the capacitor structure 206 is electrically connected to the capacitor structure 202 through at least one via (e.g., the vias 29a and 29b in FIG. 6). Depending on implementation requirements, the IC 20 may include a digital circuit layout area 205.

Referring to FIG. 5, the capacitor structure 206 includes a plurality of identical/similar unit layouts including a third electrode unit layout 230. FIG. 6 shows an embodiment of the third electrode unit layout 230. As shown in FIG. 6, all metal traces of the third electrode unit layout 230 (i.e., the metal traces 230a of the oblique pattern and the metal traces 230b of the dot pattern in FIG. 6) are parallel to the X direction; in an alternative embodiment, these metal traces are parallel to the Y direction. The via 29a (i.e., any white square on the metal trace 230a of the oblique pattern in FIG. 6) is used to electrically connect the metal traces 230a of a first part of the third electrode unit layout 230 to the metal traces 210a of the first part of the first electrode unit layout 210. The via 29b (i.e., any black square on the metal trace 230b of the dot pattern in FIG. 6) is used to electrically connect the metal traces 230b of a second part of the third electrode unit layout 230 to metal traces 210b of the second part of the first electrode unit layout 210.

Referring to FIGS. 3 to 6, in an implementation example, there is a dielectric (not shown in the figures) between the metal traces 230a of the first part of the third electrode unit layout 230 and the metal traces 230b of the second part of the third electrode unit layout 230 to form an MOM capacitor. In an implementation example, there is a dielectric (not shown in the figures) between at least a part of the third electrode unit layout 230 and at least a part of the first electrode unit layout 210 (or alternatively, the second electrode unit layout 220) to form an MOM capacitor. In an implementation example, the third electrode unit layout 230 is located directly below/above the first electrode unit layout 210 to improve the compactness of the semiconductor capacitor structure 200 and increase the capacitance of the semiconductor capacitor structure 200; more specifically, the range of the third electrode unit layout 230 is completely included in the range of the downward/upward vertical projection of the first electrode unit layout 210, or the range of the upward/downward vertical projection of the third electrode unit layout 230 completely includes the range of the first capacitor electrode unit layout 210.

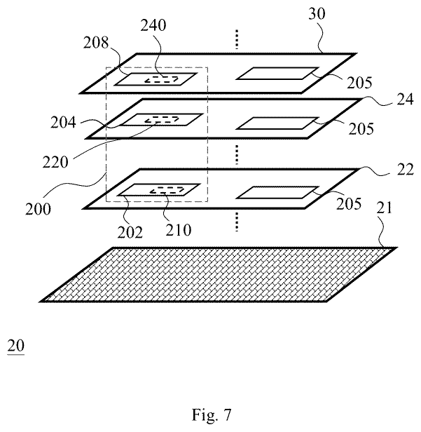

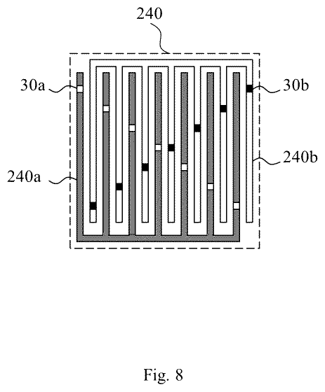

FIG. 7 shows another embodiment of the semiconductor capacitor structure of an IC circuit of the present disclosure. Compared with FIG. 2, the IC 20 of FIG. 7 further includes a second routing-direction-turnable metal layer 30, and the semiconductor capacitor structure 200 includes a part formed on the first routing-direction-non-turnable metal layer 22, a part formed on the first routing-direction-turnable metal layer 24, and a part formed on the second routing-direction-turnable metal layer 30. In addition to the aforementioned capacitor structures 202 and 204, the semiconductor capacitor structure 200 further includes: a capacitor structure 208 located on the second routing-direction-turnable metal layer 30, wherein the capacitor structure 208 is electrically connected to the capacitor structure 204 through at least one via (e.g., the vias 30a and 30b in FIG. 8).

Referring to FIG. 7, the capacitor structure 208 includes a plurality of identical/similar unit layouts including a fourth electrode unit layout 240. FIG. 8 shows an embodiment of the fourth electrode unit layout 240 including a first part having metal traces 240a and a second part having metal traces 240b. Referring to FIGS. 4 and 7-8, in order to further increase the capacitance of the semiconductor capacitor structure 200, when the metal traces 240a and the metal traces 220b are electrically connected to different voltage terminals, the position of the metal traces 240a of a first part of the fourth electrode unit layout 240 is aligned with the position of the metal traces 220b of the second part of the second electrode unit layout 220 to efficiently contribute capacitance; when the metal traces 240b and the metal traces 220a are electrically connected to different voltage terminals, the position of the metal traces 240b of a second part of the fourth electrode unit layout 240 is aligned with the position of the metal traces 220a of the first part of the second electrode unit layout 220 to efficiently contribute capacitance. It is noted that the implementation of the present invention is not limited to the above-mentioned alignment features.

It is noted that people having ordinary skill in the art can selectively implement some or all of the technical features in any of the foregoing embodiments or selectively implement a combination of some or all of the technical features in several of the foregoing embodiments to implement the present invention provided that such implementation is possible.

To sum up, the semiconductor capacitor structure of an IC of the present disclosure includes a part formed on a routing-direction-turnable metal layer of the IC and a part formed on a routing-direction-non-turnable metal layer of the IC so as to make the design flexible and increase the capacitance.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A semiconductor capacitor structure of an integrated circuit (IC), the IC including a first routing-direction-non-turnable metal layer and a routing-direction-turnable metal layer, the semiconductor capacitor structure comprising:
a first electrode unit layout located on the first routing-direction-non-turnable metal layer, wherein all metal traces located on the first routing-direction-non-turnable metal layer including metal traces of the first electrode unit layout are parallel to a first direction;
a second electrode unit layout, located on the routing-direction-turnable metal layer, including a first potential part and a second potential part, wherein each of the first potential part and the second potential part includes metal traces parallel to the first direction and metal traces parallel to a second direction, the first potential part is coupled to a first voltage terminal used to provide a first voltage, and the second potential part is coupled to a second voltage terminal used to provide a second voltage different from the first voltage; and
a dielectric located between the first potential part and the second potential part, wherein all or a first part of the metal traces of the first electrode unit layout is electrically connected to the first potential part of the second electrode unit layout through a first via.

2. The semiconductor capacitor structure of the IC of claim 1, wherein only the first part of the metal traces of the first electrode unit layout is electrically connected to the first potential part of the second electrode unit layout through the first via, and the metal traces of the first electrode unit layout include a second part electrically connected to the second potential part of the second electrode unit layout through a second via.

3. The semiconductor capacitor structure of the IC of claim 1, further comprising: another dielectric located between at least a part of the metal traces of the first electrode unit layout and at least a part of metal traces of the second electrode unit layout.

4. The semiconductor capacitor structure of the IC of claim 1, wherein the IC further includes
a second routing-direction-non-turnable metal layer and the semiconductor capacitor structure further comprises:
a third electrode unit layout located on the second routing-direction-non-turnable metal layer, wherein all metal traces located on the second routing-direction-non-turnable metal layer including metal traces of the third electrode unit layout are parallel to the second direction,
wherein all or a first part of the metal traces of the third electrode unit layout is electrically connected to all or the first part of the metal traces of the first electrode unit layout through a third via and consequently electrically connected to the first potential part of the second electrode unit layout.

5. The semiconductor capacitor structure of the IC of claim 4, wherein: only the first part of the metal traces of the third electrode unit layout is electrically connected to the first part of the metal traces of the first electrode unit layout through the third via; the metal traces of the third electrode unit layout include a second part; and the second part of the metal traces of the third electrode unit layout is electrically connected to a second part of the metal traces of the first electrode unit layout through a fourth via and consequently electrically connected to the second potential part of the second electrode unit layout.

6. A semiconductor capacitor structure of an integrated circuit (IC), the IC including a first routing-direction-non-turnable metal layer and a routing-direction-turnable metal layer, the semiconductor capacitor structure comprising:
a first electrode unit layout located on the first routing-direction-non-turnable metal layer, wherein all metal traces located on the first routing-direction-non-turnable metal layer including metal traces of the first electrode unit layout are parallel to a first direction, the metal traces of the first electrode unit layout include a first potential part and a second potential part, the first potential part is coupled to a first voltage terminal used to provide a first voltage, and the second potential part is coupled to a second voltage terminal used to provide a second voltage different from the first voltage;
a dielectric located between the first potential part and the second potential part; and
a second electrode unit layout located on the routing-direction-turnable metal layer, wherein metal traces of the second electrode unit layout include a part parallel to the first direction and another part parallel to a second direction,
wherein the first potential part of the metal traces of the first electrode unit layout is electrically connected to at least a part of the metal traces of the second electrode unit layout through a first via.

7. The semiconductor capacitor structure of the IC of claim 6, wherein the first via is used to electrically connect the first potential part of the metal traces of the first electrode unit layout to a first part of the metal traces of the second electrode unit layout, and the second potential part of the metal traces of the first electrode unit layout is electrically connected to a second part of the metal traces of the second electrode unit layout through a second via.

8. The semiconductor capacitor structure of the IC of claim 6, further comprising: another dielectric located between at least a part of the metal traces of the first electrode unit layout and at least a part of the metal traces of the second electrode unit layout.

9. The semiconductor capacitor structure of the IC of claim 6, wherein the IC further includes a second routing-direction-non-turnable metal layer and the semiconductor capacitor structure further comprises:
a third electrode unit layout located on the second routing-direction-non-turnable metal layer, wherein all metal traces located on the second routing-direction-non-turnable metal layer including metal traces of the third electrode unit layout are parallel to the second direction,
wherein at least a part of the metal traces of the third electrode unit layout is electrically connected to the first potential part of the metal traces of the first electrode unit layout through a third via.

10. The semiconductor capacitor structure of the IC of claim 9, wherein the metal traces of the third electrode unit layout include a first part and a second part, the third via is used to electrically connect the first part of the metal traces of the third electrode unit layout to the first potential part of the metal traces of the first electrode unit layout, and the second part of the metal traces of the third electrode unit layout is electrically connected to the second potential part of the metal traces of the first electrode unit layout through a fourth via.
